(19) United States
(12) Patent Application Publication
(10) Pub. No.: US 2025/0096170 A1
(43) Pub. Date: Mar. 20, 2025

(54) BONDING STRUCTURE, SEMICONDUCTOR DEVICE INCLUDING THE SAME AND METHOD OF MANUFACTURING THE SEMICONDUCTOR DEVICE

(71) Applicant: SK hynix Inc., Gyeonggi-do (KR)

(72) Inventors: Byung Ho LEE, Gyeonggi-do (KR); Jin Won PARK, Gyeonggi-do (KR)

(21) Appl. No.: 18/539,647

(22) Filed: Dec. 14, 2023

(30) Foreign Application Priority Data
Sep. 15, 2023 (KR) 10-2023-012299

(51) Int. Cl. H01L 23/00; H01L 25/065

(52) U.S. Cl. CPC H01L 24/08; H01L 25/0657; H01L 24/03; H01L 2224/03616; H01L 2224/08059; H01L 2224/08147; H01L 2225/06513; H01L 2924/1431; H01L 2924/1434

(57) ABSTRACT

A bonding structure may include a non-conductive layer and at least one conductive pad. The non-conductive layer may have a first surface and a second surface opposite to the first surface. The conductive pad may be arranged in the non-conductive pad. The conductive pad may include a vertical pattern portion and at least one volume compensation portion. The vertical pattern portion may extend from the first surface to the second surface in the non-conductive layer. The volume compensation portion may be formed on a sidewall of the vertical pattern portion.

### CROSS-REFERENCES TO RELATED APPLICATION

The present application claims priority under 35 U.S.C. § 119(a) to Korean application number 10-2023-0122998, filed on Sep. 15, 2023, in the Korean Intellectual Property Office, which is incorporated herein by reference in its entirety.

### BACKGROUND

### 1. Technical Field

Various embodiments generally relate to a bonding structure, a semiconductor device including the bonding structure and a method of manufacturing the semiconductor device, more particularly, to a bonding structure including a conductive pad that may be capable of preventing a bonding error, a semiconductor device including the bonding structure, and a method of manufacturing the semiconductor device.

### 2. Related Art

As an electronic device may have been decreased in a size, a size of a die in the semiconductor device may also be gradually reduced. Further, in order to satisfy a need of the electronic device having a massive capacity, a plurality of the dies may be stacked to form an assembly.

In order to effectively assemble the dies having a fine size, the semiconductor devices may be directly bonded to each other by a hybrid bonding process.

The hybrid bonding process may directly bond the semiconductor devices to each other without an adhesive. Each of the semiconductor devices may include a bonding structure. The bonding structure may include a plurality of bonding pads and a non-conductive layer on a bonding surface of each of the semiconductor devices.

Further, the semiconductor devices may be stacked to face the bonding structures to each other. A force may be applied to the semiconductor devices by an annealing process to thermally expand the conductive pads of the bonding structures, thereby bonding the bonding structures to each other.

The conductive pads of the bonding structure may be connected to a signal line, a power line and voltage transmission lines in the semiconductor device. Thus, as an integration degree of the semiconductor device may have been increased, a size of the conductive pad may be greatly decreased.

However, although a sufficient force may be applied to the conductive pad, the small size of the conductive pad may not be expanded to a bondable size. As a result, a bonding error of the semiconductor device may be generated.

### SUMMARY

According to example embodiments, there may be provided a bonding structure. The bonding structure may include a non-conductive layer and at least one conductive pad. The non-conductive layer may have a first surface and a second surface opposite to the first surface. The conductive pad may be arranged in the non-conductive pad. The conductive pad may include a vertical pattern portion and at least one volume compensation portion. The vertical pattern portion may extend from the first surface to the second surface in the non-conductive layer. The volume compensation portion may be formed on a sidewall of the vertical pattern portion.

According to example embodiments, there may be provided a semiconductor device. The semiconductor device may include a first semiconductor component and a second semiconductor component hybrid-bonded to each other. The first semiconductor component may include a first device layer and a first bonding structure electrically connected with the first device layer. The second semiconductor component may include a second device layer and a second bonding structure. The second bonding structure may be electrically connected with the second device layer. The second bonding structure may be hybrid-bonded to the first bonding structure. Each of the first bonding structure and the second bonding structure may include at least one conductive pad and a non-conductive layer. The conductive pad may be exposed toward a bonding surface. The non-conductive layer may be arranged outside the conductive pad. At least one of the conductive pads in the first and second bonding structures may include a vertical pattern portion and at least one volume compensation portion. The vertical pattern portion may be formed through the non-conductive layer. The volume compensation portion may be formed on a sidewall of the vertical pattern portion.

In example embodiments, the volume compensation portion may include a plurality of volume compensation portions.

In example embodiments, the volume compensation portions may have a uniform shape. The volume compensation portions may be regularly arranged in a thick direction of the vertical pattern portion. In some embodiments, the volume compensation portions may be different from each other.

According to example embodiments, there may be provided a method of manufacturing a semiconductor device. In the method of manufacturing the semiconductor device comprises: forming a first device layer on a first semiconductor component; forming a first bonding structure on the first device layer; forming a second device layer on a second semiconductor component; forming a second bonding structure on the second device layer; stacking the second semiconductor component on the first semiconductor component to face the first conductive pad of the first bonding structure and the second conductive pad of the second bonding structure each other; and hybrid-bonding the first bonding structure and the second bonding structure to each other. The first bonding structure includes at least one first conductive pad, a first non-conductive layer, and a first volume compensation portion, the first non-conductive layer surrounding the first conductive pad. The second bonding structure includes at least one second conductive pad, a second non-conductive layer, and a second volume compensation portion, the second non-conductive layer surrounding the second conductive pad.

The first bonding structure may be formed in following manners. Firstly, the first non-conductive layer may be formed over the first device layer. A mask pattern may be formed over the first non-conductive layer and sidewalls of the mask pattern are spaced apart from each other by a set width. A through hole is formed in the first non-conductive layer using the mask pattern to expose a conductive component of the first device layer. The mask pattern is removed. Then, the through hole is filled with a conductive material to form the first conductive pad, thereby forming the first bonding structure The through hole may be formed by etching the first non-conductive layer to increase an inner diameter of the through hole than the set width.

Further, the second bonding structure may be formed in following manners. Firstly, the second non-conductive layer may be formed over the second device layer. A mask pattern may be formed over the second non-conductive layer. For example, the mask pattern has a hole with a set width. A through hole may be formed in the first non-conductive layer using the mask pattern to expose a conductive component of the second device layer. The mask pattern is removed after forming the through hole. The through hole may be filled with a conductive material to form the second conductive pad, thereby forming the second bonding structure. The through hole may be formed by etching the first non-conductive layer to increase an inner diameter of the through hole than the set width.

According to example embodiments, the volume compensation portion may be protruded from the sidewall of the bonding pad to prevent a bonding error caused by a deficiency of a conductive material.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1A is a cross-sectional view schematic illustrating a bonding structure in accordance with example embodiments;

FIG. 1B is a perspective view illustrating a conductive pad in accordance with example embodiments;

FIGS. 2A and 2B are plan view schematics illustrating a conductive pad in accordance with example embodiments;

FIGS. 3A to 3F are cross-sectional view schematics illustrating a method of manufacturing a bonding structure in accordance with example embodiments;

FIGS. 4A to 4C are cross-sectional view schematics illustrating a method of manufacturing a bonding structure in accordance with example embodiments;

FIG. 5 is a cross-sectional view schematic illustrating a method of manufacturing a bonding structure in accordance with example embodiments;

FIGS. 6, 7A, 7B and 8 are cross-sectional view schematics illustrating bonding structures in accordance with example embodiments; and

FIGS. 9 and 10 are cross-sectional view schematics illustrating a method of manufacturing a semiconductor device by a hybrid-bonding process in accordance with example embodiments of the present invention.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the scope of the present invention.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and scope of the present invention.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

The term “substantially,” as employed herein concerning a specific parameter, property, or condition, denotes adherence to a degree recognizable by one of ordinary skill in the art. This adherence implies meeting the given parameter, property, or condition within an acceptable range of variance, often within established tolerances. For instance, the degree of acceptable range of variance could be no less than 90.0%, 95.0%, 99.0%, 99.9%, or complete adherence (100.0%), contingent upon the particular parameter, property, or condition being evaluated.

In this context, when “about” or “approximately” precedes a numerical value for a specific parameter, it encompasses not only the stated numerical value but also a reasonable range of variance. This variance accounts for what would be deemed acceptable by an one of ordinary skill in the art. For instance, this range could include values from 90.0 percent to 110.0 percent of the stated numerical value, or narrower ranges such as 95.0 percent to 105.0 percent, 97.5 percent to 102.5 percent, 99.0 percent to 101.0 percent, 99.5 percent to 100.5 percent, or 99.9 percent to 100.1 percent, depending on the specific parameter under consideration.

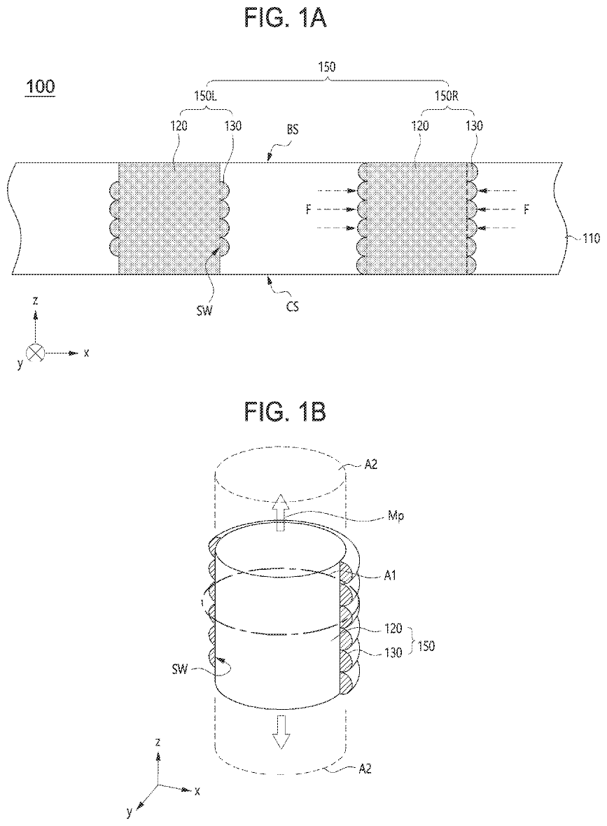

FIG. 1A is a cross-sectional view schematic illustrating a bonding structure in accordance with example embodiments and FIG. 1B is a perspective view illustrating a conductive pad in accordance with example embodiments of the present invention.

Referring to FIGS. 1A and 1B, a bonding structure 100 of example embodiments may include a non-conductive layer 110 and at least one conductive pad 150 formed in the non-conductive layer 110.

A lower surface of the bonding structure 100 may include a contact surface CS electrically connected to a device layer of a semiconductor component. An upper surface of the bonding structure 100 may include a bonding surface BS to be bonded to a bonding structure of other semiconductor components. In example embodiments, the semiconductor component may include a semiconductor wafer, a semiconductor substrate, an interposer layer, a semiconductor chip, etc. The contact surface CS may include a contact surface of the non-conductive layer 110 and the conductive pad 150. The bonding surface BS may include a bonding surface of the non-conductive layer 110 and the conductive pad 150. For example, the boding surface BS may be referred as a first surface of the bonding structure 100 and the contact surface CS may be referred as a second surface of the bonding structure 100.

The non-conductive layer 110 may include at least one dielectric layer. In example embodiments, the non-conductive layer 110 may include at least one of a silicon-containing layer, an oxygen-containing layer, a nitrogen-containing layer, a carbon-containing layer, a silicon oxide layer, a silicon nitride layer, a silicon oxynitride layer, a silicon carbon nitride layer, a silicon carbide layer and a metal insulation layer. In some embodiments, the non-conductive layer 110 may include a plurality of stacked dielectric layers. The non-conductive layer 110 may be referred as a bonding insulation layer, an insulation layer, a dielectric layer, etc.

The conductive pad 150 may include a conductive material in which a conductive material-conductive material bond, for example, a metal-metal bond may be possible. For example, the conductive pad 150 may include at least one of copper, gold, silver, tungsten, nickel, an alloy thereof, etc., but not limited thereto.

When a plurality of the conductive pads 150 is formed in the non-conductive layer 110, a width of each of the conductive pads 150 and a pitch between the conductive pads 150 may be determined based on an integration degree of the device layer.

In example embodiments, the conductive pad 150 may include a vertical pattern portion 120 and at least one volume compensation portion 130.

The vertical pattern portion 120 may be extended in a thickness direction of the non-conductive layer 110, for example, a vertical direction, i.e., a z-direction. For example, the vertical pattern portion 120 may have a pillar shape formed through the non-conductive layer 110. The vertical pattern portion 120 may have an upper width and a lower width different from the upper width by the thickness of the non-conductive layer 110, process recipes, etc. However, in example embodiments, the upper width and the lower width of the vertical pattern portion 120 may be substantially the same.

The volume compensation portion 130 may be arranged on a sidewall SW of the vertical pattern portion 120. The volume compensation portion 130 may be protruded from the sidewall SW of the vertical pattern portion 120 toward the non-conductive layer 110 on horizontal direction, i.e., an x-direction and a y-direction.

The volume compensation portion 130 may include a conductive material substantially the same as the conductive material of the vertical pattern portion 120. For conveniences of explanations, the vertical pattern portion 120 and the volume compensation portion 130 may be separated. However, the vertical pattern portion 120 and the volume compensation portion 130 may be one pattern without a boundary or an interface between the vertical pattern portion 120 and the volume compensation portion 130. Thus, the sidewall SW of the vertical pattern portion 120 may be a virtual portion indicated by the conveniences of the explanations.

A hybrid bonding process may include an annealing process for bonding the bonding structures 100 to each other. The annealing process may be performed within a temperature range for inducing a thermal expansion of the conductive pad 150.

When the annealing process is performed, a compressive stress F may be generated from the non-conductive layer 110 having a relatively low thermal expansion coefficient to the conductive pad 150 having a relatively high thermal expansion coefficient. As shown in FIG. 1A, the compressive stress F may be generated along the x-direction and the y-direction, i.e., a horizontal direction to expand the conductive pad 150 along the z-direction, i.e., the vertical direction. In FIG. 1B, a reference numeral Mp may be a direction of the thermal expansion. The direction of the thermal expansion may be directed to a space having the lowermost stress based on the hardness of a peripheral material or a stress distribution.

Various ways may be performed for effectively bonding the bonding structures 100 to each other. For example, in order to control the compressive stress F, a component and a structure of the non-conductive layer may be changed. However, although the compressive stress F may be controlled by changing the component and the structure of the non-conductive layer, when a physical size of the conductive pad is reduced, a bonding error may be still generated due to a small amount of the conductive material in the conductive pad participated in the thermal expansion.

In example embodiments, the volume compensation portion 130 may be formed outside the vertical pattern portion 120 having a fine pattern to increase an amount of the conductive material in the conductive pad 150 contributing to the thermal expansion.

In example embodiments, a plurality of the volume compensation portions 130 may be arranged continuously or non-continuously on the entire sidewall SW of the vertical pattern portion 120. Thus, a surface of the volume compensation portions 130 facing the non-conductive layer 110 may have an uneven structure or a partially uneven structure.

Therefore, an area of the conductive pad 150 on an x-y plane (hereinafter, referred to as a cross-sectional area) may be changed by the thickness of the conductive pad 150 defined in, for example, the z-direction.

For example, an area A1 of the conductive pad 150 with the volume compensation portion 130 on the x-y plane (hereinafter, referred to as a first cross sectional area) may be larger than an area A2 of the vertical pattern portion 120 on the x-y plane (hereafter, referred to as a second cross-sectional area). Thus, the volume compensation portion 130 may function as an area expander of the conductive pad 150.

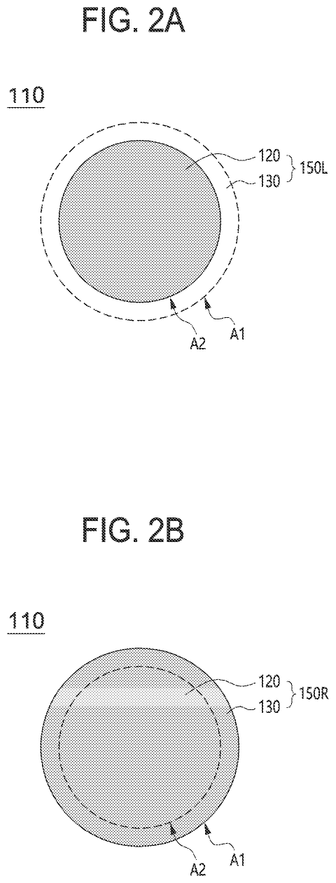

FIGS. 2A and 2B are plan view schematics illustrating a conductive pad in accordance with example embodiments of the present invention. FIGS. 2A and 2B show a planar structure of the conductive pad 150 viewed from the bonding surface BS in FIG. 1.

When the volume compensation portion 130 is spaced apart from the bonding surface BS similarly to the conductive pad 150L in FIG. 1A, as shown in FIG. 2A, the conducive pad 150L exposed through the bonding surface BS may have the second cross-sectional area A2 corresponding to a cross-sectional area of the vertical pattern portion 120. When the volume compensation portion 130 contacts with the bonding surface BS similarly to the conductive pad 150R in FIG. 1A, as shown in FIG. 2B, the conductive pad 150R exposed through the bonding surface BS may have the first cross-sectional area A1 corresponding to a sum of the cross-sectional area of the vertical pattern portion 120 and the cross-sectional area of the volume compensation portion 130.

That is, the cross-sectional areas of the conductive pads 150L and 150R on the bonding surface BS may be controlled in accordance with positions of the volume compensation portion 130. Thus, the positions of the volume compensation portion 130 may be changed by a fine pitch section and a pitch margin section. In example embodiments, the conductive pads 150L and 150R viewed from the bonding surface BS may be exemplarily shown. In some embodiments, the conductive pads 150L and 150R viewed from the contact surface CS may be similarly applied.

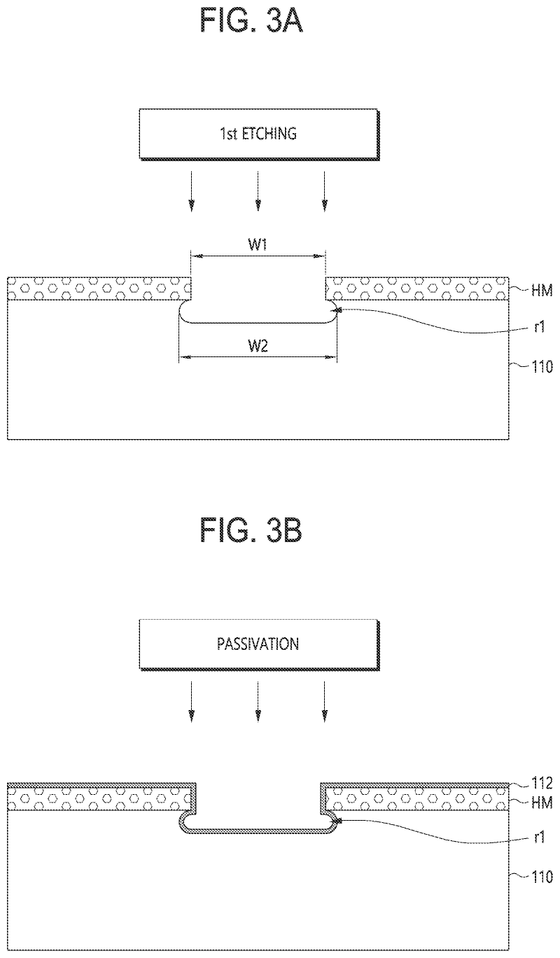

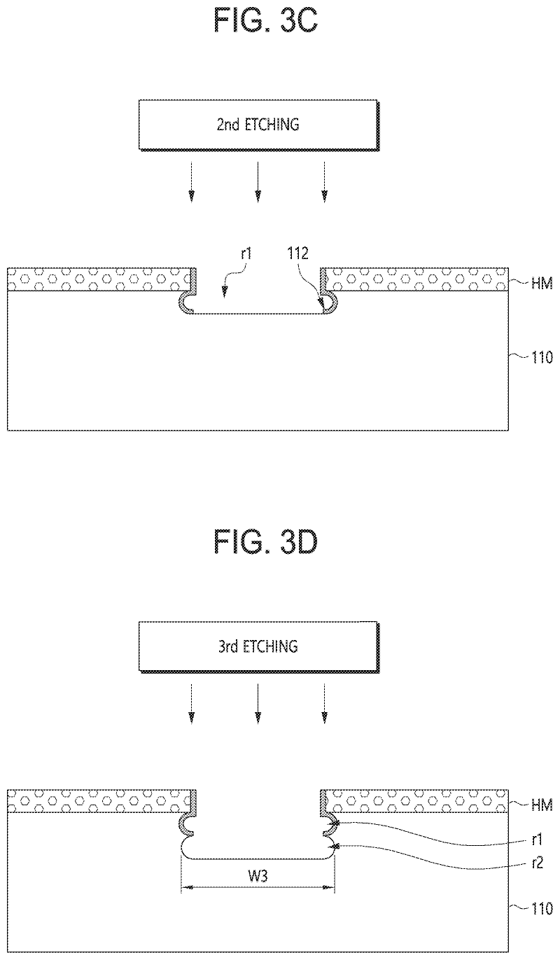

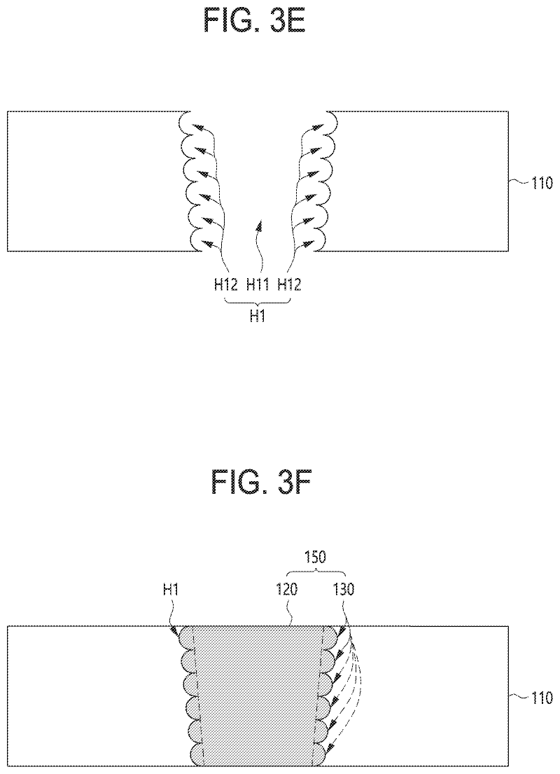

FIGS. 3A to 3F are cross-sectional view schematics illustrating a method of manufacturing a bonding structure in accordance with example embodiments of the present invention.

Referring to FIG. 3A, the non-conductive layer 110 may be formed over or on a surface of the semiconductor component. The surface of the semiconductor component may correspond to an uppermost surface of a device layer or a rear surface of a substrate. The non-conductive layer 110 may include at least one dielectric layer. In example embodiments, the non-conductive layer 110 may include a plurality of stacked dielectric layers. The dielectric layers may include a same material or different materials.

A mask pattern HM for defining a region where a conductive pad is to be formed may be formed on the non-conductive layer 110. For example, the mask pattern HM may include a hard mask layer. The mask pattern HM may include a material having an etching selectivity with respect to the non-conductive layer 110, or a photoresist pattern. In order to define the conductive pad having a fine width, a distance between sidewalls of the mask pattern HM may correspond to a first width W1.

The non-conductive layer 110 may be etched using the mask pattern HM. A first etching process may be performed to form a first recess r1 by etching a portion of the non-conductive layer 110. The first etching may include an isotropic etching. Thus, a sidewall of the first recess r1 may be protruded in a round shape toward the non-conductive layer 110 than the sidewall of the mask pattern HM. The first recess r1 may have a second width W2 wider than the first width W1. When a width is changed due to a curvature of the sidewall, the second width W2 of the first recess r1 may correspond to the longest distance among horizontal distances between opposite sidewalls.

Referring to FIG. 3B, a passivation layer 112 may be formed on surfaces of the first recess r1 and the mask pattern HM. The passivation layer 112 may be formed by providing a gas to the surface of the non-conductive layer 110 with the first recess r1. The passivation layer 112 may include a material having an etching selectivity with respect to the non-conductive layer 110. For example, the passivation layer 112 may be formed in a plasma deposition apparatus. Further, the passivation layer 112 may be deposited under a condition that a bias for generating plasma is not provided.

Referring to FIG. 3C, a second etching process may be performed to partially remove the passivation layer 112. For example, the second etching process may include an anisotropic etching process. Thus, the passivation layer 112 on a bottom surface of the first recess r1 and an upper surface of the mask pattern HM may be selectively removed by the second etching process. Further, the second etching process may include a plasma etching process performed under a condition that a bias is applied in a plasma apparatus. The non-conductive layer 110 on the bottom surface of the first recess r1 may be exposed by the second etching process.

Referring to FIG. 3D, the bottom surface of the first recess r1 may be removed by a third etching process to form a second recess r2. The third etching process may include an isotropic etching process. Thus, the second recess r2 may be continuously formed from the first recess r1. When the third etching process have recipes substantially the same as recipes of the first etching process, the second recess r2 may have a third width W3 substantially the same as the second width W2. In some embodiments, the third width W3 may be wider than the first width W1 and different from the second width W2 in accordance with the recipes of the third etching process.

The processes in FIGS. 3B to 3D may be repeatedly performed until a conductive portion of the semiconductor component under the non-conductive layer 110, for example, a conductive component of the device layer, or a conductive component of the substrate is exposed to form a through hole H1 as shown in FIG. 3E. The through hole H1 may include a first portion H11 and a second portion H12. The first portion H11 may be vertically formed from the upper surface to the lower surface in the non-conductive layer 110. The second portion H12 may be horizontally retreated from a side surface of the first portion H11. A remaining mask pattern HM and a remaining passivation layer 112 may be removed by a cleaning process.

Referring to FIG. 3F, the first and second portions H11 and H12 of the through hole H1 may be filled with a conductive layer. For example, the conductive layer may include at least one of copper, gold, tungsten, nickel, silver and an alloy thereof. The conductive layer may be planarized to form a conductive pad 150 in the through hole H1. The conductive layer may be planarized by a chemical mechanical polishing (CMP) process. The conductive pad 150 may include the vertical pattern portion 120 and the volume compensation portion 130. The vertical pattern portion 120 may be formed in the first portion H11 of the through hole H1. The volume compensation portion 130 may be formed in the second portion H12 of the through hole H1. Thus, in the conductive pad 150 of example embodiments satisfies an actual pitch gap or a width rule, and the conductive layer in the volume compensation portion 130 may participate in the thermal expansion to prevent a bonding error.

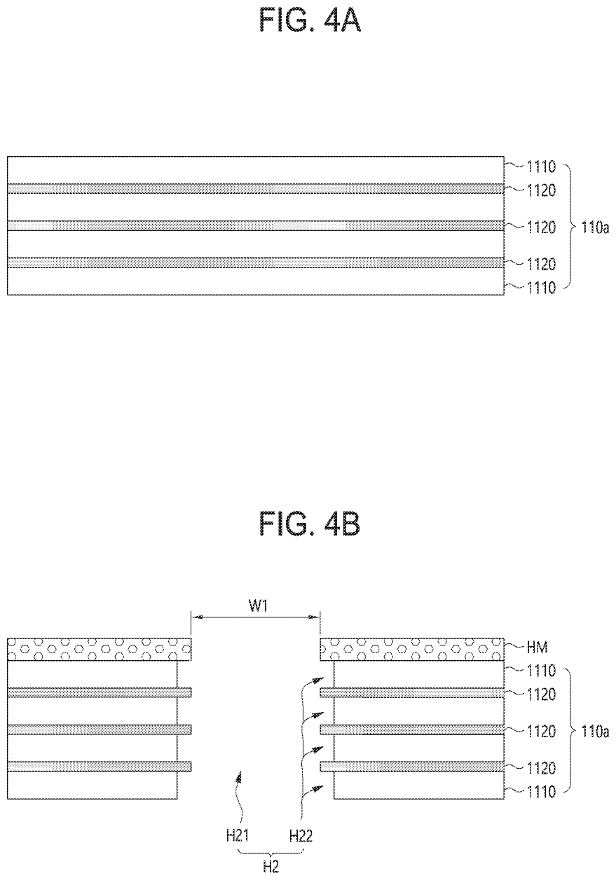

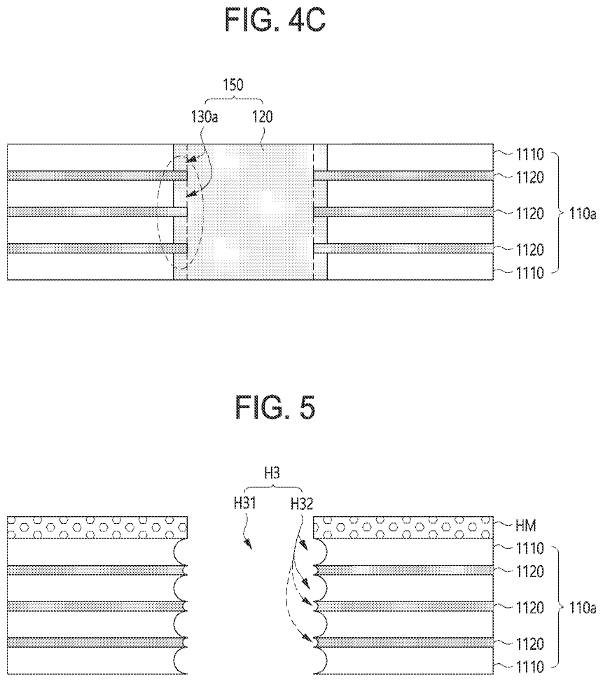

FIGS. 4A to 4C are cross-sectional view schematics illustrating a method of manufacturing a bonding structure in accordance with example embodiments and FIG. 5 is a cross-sectional view schematic illustrating a method of manufacturing a bonding structure in accordance with example embodiments of the present invention.

Referring to FIG. 4A, a first dielectric layer 1110 and a second dielectric layer 1120 may have different etching selectivities. The first and second dielectric layers may be alternately stacked to form a non-conductive layer 110a. In some embodiments, the non-conductive layer 110a may have first dielectric layers 1110 disposed at the uppermost and lowermost layers.

In some embodiments, the first dielectric layer 1110 and the second dielectric layer 1120 may have different etching rates with respect to a specific etchant. In some embodiments, the first dielectric layer 1110 and the second dielectric layer 1120 may have substantially the same thickness or different thicknesses. Further, a plurality of the first dielectric layers 1110 may have a uniform thickness or different thicknesses depending on their positions. Similarly, a plurality of the second dielectric layers 1120 may have substantially the same thickness or different thicknesses. The etchant may include an etching gas or an etching solution.

Referring to FIG. 4B, a mask pattern HM may be formed over or on the non-conductive layer 110a. A distance between sidewalls of the mask pattern HM may correspond to the first width W1.

The first and second dielectric layers 1110 and 1120 may be etched using the mask patterns HM to form a through hole H2 in the non-conductive layer 110a. The etching process may include an anisotropic etching process. For example, the anisotropic etching process may use an etching gas. When the etching rate of the first dielectric layer 1110 is greater than the etching rate of the second dielectric layer 1120, the sidewall of the through hole H2 corresponding to the first dielectric layer 1110 may be inwardly retreated toward the first dielectric layer 1110 than an interface of the mask pattern HM. The sidewall of the through hole H2 corresponding to the second dielectric layer 1120 may correspond to the interface of the mask pattern HM. Thus, the through hole H2 may include a first portion H21 and a second portion H22. The first portion H21 may be vertically formed through an upper surface and a lower surface in the non-conductive layer 110a. The second portion H22 may be retreated from a side surface of the first portion H21 in the horizontal direction.

Referring to FIG. 4C, the mask pattern HM may then be removed. The through hole H2 may be filled with a conductive layer. The conductive layer may be planarized to form a conductive layer 150 in the through hole H2. The conductive pad 150 may include a vertical pattern portion 120 and a volume compensation portion 130a. The vertical pattern portion 120 may be formed in the first portion H21 of the through hole H2. The volume compensation portion 130a may be formed in the second portion H22 of the through hole H2. The conductive material in the volume compensation portion 130a may participate in the thermal expansion of the hybrid-bonding process.

In some embodiments, referring to FIG. 5, the etching process for forming the through hole H2 in FIG. 4B may include an isotropic etching process. Thus, a sidewall of a through hole H3 corresponding to the first dielectric layer 1110 and a sidewall of the through hole H3 corresponding to the second dielectric layer 1120 may be inwardly retreated than the interface of the mask pattern HM. Second portions H32 of the through hole H3 with a volume compensation portion may have different sizes by differences between materials and thicknesses of the first and second dielectric layers 1110 and 1120. Thus, a conductive pad in the through hole H3 may have various widths in accordance with thicknesses of the conductive pad. A reference numeral H31 may be a first portion of the through hole H3 formed through the upper surface and the lower surface of the non-conductive layer 110a.

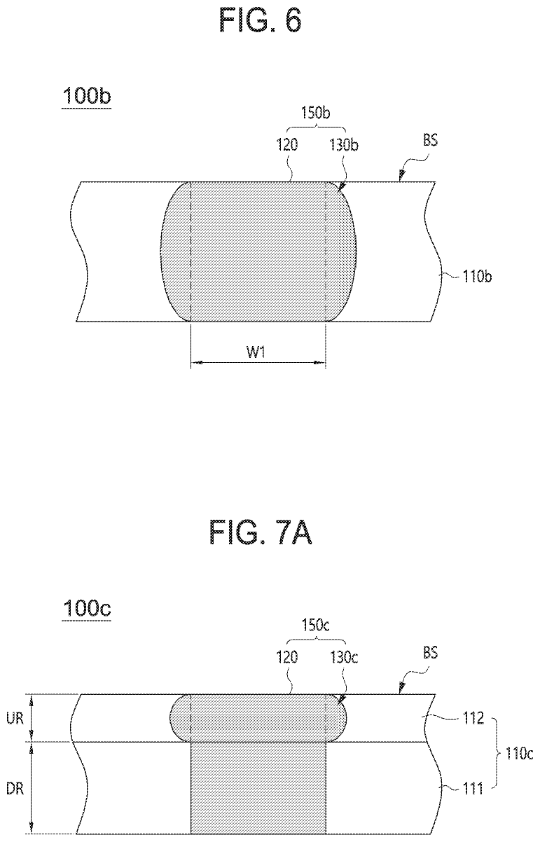

FIGS. 6, 7A, 7B and 8 are cross-sectional view schematics illustrating bonding structures in accordance with example embodiments of the present invention.

Referring to FIG. 6, a bonding structure 100b of example embodiments may include a non-conductive layer 110b and a conductive pad 150b. The non-conductive layer 110b may include at least one dielectric layer.

The conductive pad 150b may include a vertical pattern portion 120 and a bow shape (curved shape) volume compensation portion 130b. The vertical pattern portion 120 may be vertically formed through the non-conductive layer 110b. The bow shape volume compensation portion 130b may be extended from a sidewall of the vertical pattern portion 120 without a boundary between a vertical pattern portion 120 and a bow shape volume compensation portion 130b. Because the volume compensation portion 130b may be built in the non-conductive layer 110b, the volume compensation portion 130b may compensate an insufficient conductive material in the thermal expansion without a change of the width W1 of the conductive pad 150b.

In example embodiments, the volume compensation portion 130b may be formed on the entire sidewall of the vertical pattern portion 120. In some embodiments, the volume compensation portion 130b may be formed on at least a part of the sidewall of the vertical pattern portion 120.

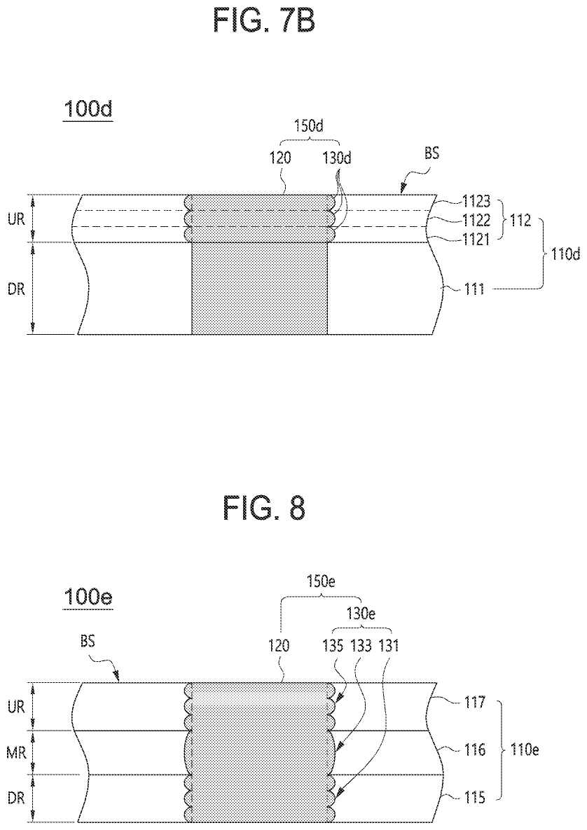

For example, referring to FIG. 7A, a bonding structure 100c may be divided into an upper region UR and a lower region DR. The upper region UR may be adjacent to the bonding surface BS. The lower region DR may be adjacent to the device layer of the semiconductor component or the bottom surface of the substrate. In some embodiments, the upper region UR may be adjacent to the device layer of the semiconductor component or the bottom surface of the substrate. The lower region DR may be adjacent to the bonding surface BS.

The bonding structure 100c of example embodiments may include a non-conductive layer 110c and a conductive pad 150c. The conductive pad 150c may include a vertical pattern portion 120 and a volume compensation portion 130c. The vertical pattern portion 120 may be formed through the non-conductive layer 110c. The volume compensation portion 130c may be formed on a sidewall of the vertical pattern portion 120. For example, the volume compensation portion 130c may be protruded in a bow shape.

In example embodiments, the non-conductive layer 110c may include a single dielectric layer, but not limited thereto. The non-conductive layer 110c may include a first dielectric layer 111 and a second dielectric layer 112. The first dielectric layer 111 may be formed in the lower region DR. The second dielectric layer 112 may be formed in the upper region UR.

Referring to FIG. 7B, a plurality of volume compensation portions 130d may be formed in the upper region UR. The second dielectric layer 112 may include a plurality of dielectric layers 1121, 1122 and 1123.

According to example embodiments, the volume compensation portions 130c and 130d may be formed in the upper region UR adjacent to the bonding surface BS of the bonding structures 100c and 100d so that a greater amount of the conductive materials may be provided to the bonding surface BS than to the contact surface CS (refer to FIG. 1A).

In example embodiments, the volume compensation portions 130c and 130d may be arranged in the upper region UR. In some embodiments, the volume compensation portion may be formed in the lower region DR.

Referring to FIG. 8, a bonding structure 100e of example embodiments may be divided into an upper region UR, a middle region MR and a lower region DR. The upper region UR may be adjacent to the bonding surface BS. The lower region DR may be adjacent to the device layer of the semiconductor component or the bottom surface of the substrate. The middle region MR may be positioned between the upper region UR and the lower region DR.

The bonding structure 100e of example embodiments may include a non-conductive layer 110e and a conductive pad 150e.

The non-conductive layer 110e may include at least one dielectric layer. In example embodiments, the non-conductive layer 110e may include a first dielectric layer 115, a second dielectric layer 116 and a third dielectric layer 117. In some embodiments, at least one of the first to third dielectric layers 115, 116 and 117 may include a plurality of dielectric layers.

The conductive pad 150e may include a vertical pattern portion 120 and a volume compensation portion 130e. The volume compensation portion 130e may include a first volume compensation portion 131, a second volume compensation portion 133 and a third volume compensation portion 135.

The first volume compensation portion 131 may be formed on a sidewall of the vertical pattern portion 120 in the lower region DR. The second volume compensation portion 133 may be formed on a sidewall of the vertical pattern portion 120 in the middle region MR. The third volume compensation portion 135 may be formed on a sidewall of the vertical pattern portion 120 in the upper region UR.

For example, the first to third volume compensation portions 131, 133 and 135 may have substantially the same shape or different shapes. That is, the volume compensation portions 131, 133 and 135 may include variable protrusion shapes depending on a thickness direction of the conductive pattern 120. In some embodiments, at least two of the first to third volume compensation portions 131, 133 and 135 may have substantially the same shape.

For example, the first volume compensation portion 131 may have a structure substantially the same as a structure of the third volume compensation portion 135. A plurality of the first volume compensation portions 131 and a plurality of the third volume compensation portions 135 may be arranged in the lower region DR and the upper region UR, respectively. Thus, an interface between the first volume compensation portion 131 and the first dielectric layer 115 and an interface between the third volume compensation portion 135 and the third dielectric layer 117 may have an uneven structure.

The second volume compensation portion 133 may have a structure different from the structure of the first and third volume compensation portions 131 and 135. For example, an interface between the second volume compensation portion 133 and the second dielectric layer 113 may have a bow shape.

In example embodiments, the first volume compensation portion 131 or the third volume compensation portion 135 may have a volume larger than a volume of the second volume compensation portion 133. Thus, a greater amount of the conductive material may be supplied to the upper region UR and the lower region DR electrically bonded to other conductive pads or other conductive components to reduce the bonding error.

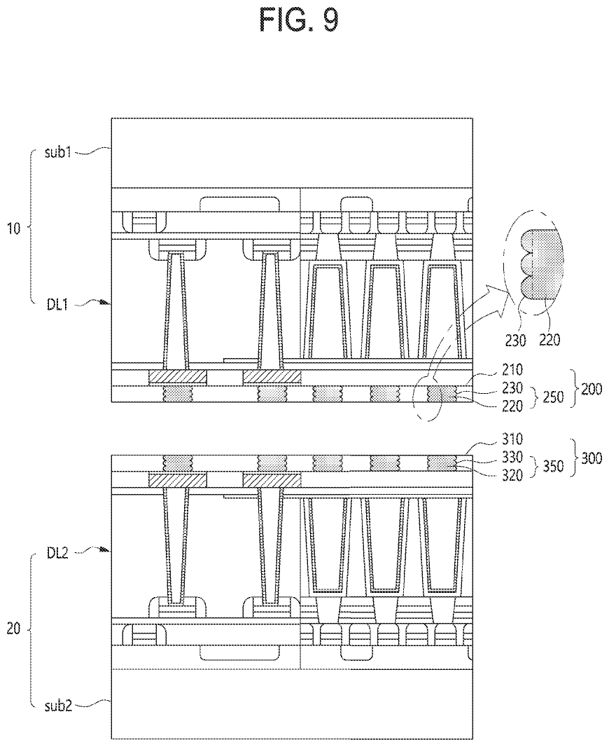

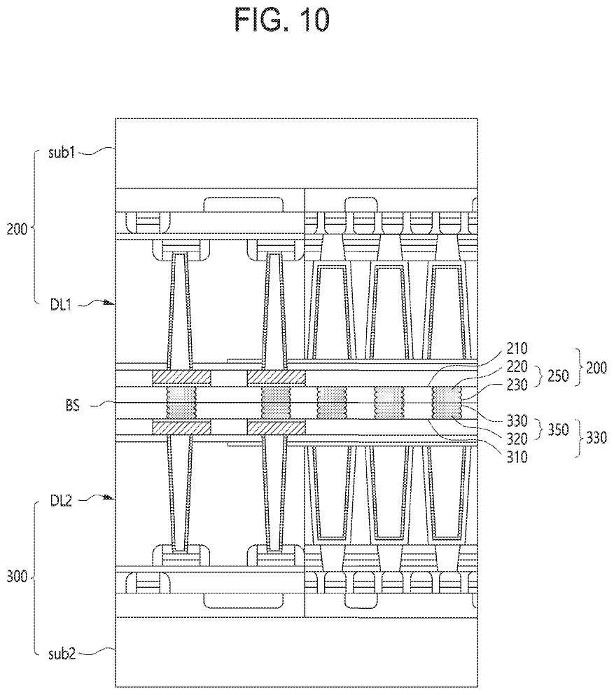

FIGS. 9 and 10 are cross-sectional view schematics illustrating a method of manufacturing a semiconductor device by a hybrid-bonding process in accordance with example embodiments of the present invention.

Referring to FIG. 9, a first semiconductor component 10 and a second semiconductor component 20 may be prepared. The first semiconductor component 10 and the second semiconductor component 20 may include devices layers DL1 and DL2, respectively, and bonding structures 200 and 300, respectively, on respective surfaces of substrates sub1 and sub2. For example, the substrates sub1 and sub2 may each include a semiconductor substrate, a supporting layer with a semiconductor layer, an interposer layer, a device layer DL1 and DL2, and etc.

The first device layer DL1 of the first semiconductor component 10 and the second device layer DL2 of the second semiconductor component 20 may have substantially the same structure or different structures. For example, the first device layer DL1 and the second device layer DL2 may include at least one of a memory device and a logic/drive circuit, but not limited thereto.

The first bonding structure 200 of the first semiconductor component 10 may include a first non-conductive layer 210 and at least one first conductive pad 250 in the first non-conductive layer 210.

The second bonding structure 300 of the second semiconductor component 20 may include a second non-conductive layer 310 and at least one second conductive pad 350 in the second non-conductive layer 310.

For example, the first bonding structure 200 and the second bonding structure 300 may have a similar structure. However, sizes and materials in elements of the first and second bonding structures 200 and 300 may be partially different from each other.

In example embodiments, one surface of the first conductive pad 250 and one surface of the second bonding pad 350 may face each other with respect to a bonding surface. The facing first and second conductive pads 250 and 350 may have substantially the same width or different widths in accordance with a pitch of a corresponding semiconductor component.

The other surface of the first conductive pad 250 may be connected to a conductive component of the first device layer DL1. The other surface of the first conductive pad 250 may be electrically connected with a conductive component in the substrate sub1. The other surface of the second conductive pad 350 may be connected to a conductive component of the second device layer DL2 or a conductive component in the substrate sub2.

The first and second conductive pads 250 and 350 may include vertical pattern portions 220 and 320 and volume compensation portions 230 and 330, respectively.

The vertical pattern portions 220 and 320 may be vertically formed through the first and second non-conductive patterns 210 and 310, respectively. One surface and the other surface may have substantially the same width.

The volume compensation portions 230 and 330 may be formed on sidewalls of the vertical pattern portions 220 and 320, respectively. The volume compensation portions 230 and 330 may include a conductive material substantially the same as a conductive material of the vertical pattern portions 220 and 320, respectively. The volume compensation portions 230 and the vertical portions 220 may form a single conductive pad without an interface. Also, the volume compensation portions 330 and the vertical pattern portions may form a single conductive pad without an interface.

The volume compensation portions 230 and 330 may be horizontally protruded from the sidewalls of the vertical pattern portions 220 and 320 toward the non-conductive layers 210 and 310, respectively. The volume compensation portions 230 and 330 may include the conductive material without effectively changing the width of the first and second conductive pads 250 and 350.

In example embodiments, the volume compensation portion 230 of the first conductive pad 250 and the volume compensation portion 330 of the second conductive pad 350 may have substantially the same structure or different structures. The volume compensation portions 230 and 330 may be formed by at least one of processes in FIGS. 1 to 8.

The second semiconductor component 20 may be stacked on the first semiconductor component 10 in such a way that the first bonding structure 200 faces the second bonding structure 300. For example, the first semiconductor component 10 and the second semiconductor component 20 may be loaded into a bonding apparatus. The bonding apparatus may be driven to face the first bonding structure 200 and the second bonding structure 300 each other to flip the first semiconductor component 10.

Referring to FIG. 10, the first semiconductor component 10 may be hybrid-bonded to the second semiconductor component 20.

For example, the first and second semiconductor components 10 and 20 may be aligned with each other, and the first conductive pad 220 and the second conductive pad 320 may face each other.

The first and second semiconductor components 10 and 20 may be pre-bonded. The pre-bonding process may include providing a force at a room temperature, for example, 20° C. to about 25° C. The force may be applied to at least one of the first and second semiconductor components 10 and 20 at the room temperature to bond the first non-conductive layer 210 to the second non-conductive layer 310.

The pre-bonded first and second semiconductor components and 20 may be finally bonded to each other by an annealing process. For example, the annealing process may be performed at a temperature for denaturing the first and second conductive pads 250 and 350 without reliabilities of the device layers DL1 and DL2, for example, about 100° C. to about 200° C.

In the first and second conductive pads 250 and 350 of example embodiments, the conductive material in the volume compensation portions 230 and 330 as well as the conductive material in the vertical pattern portions 220 and 320 may participate in the thermal expansion of the annealing process to reduce the bonding error.

Further, the volume compensation portions 230 and 330 of the first and second conductive pads 250 and 350 may be built in the non-conductive layers 210 and 310, and not exposed to outside. Thus, the first and second conductive pads 250 and 350 on the bonding surface BS may have fine widths.

According to example embodiments, the volume compensation portion may be protruded from the sidewall of the bonding pad to prevent a bonding error caused by a deficiency of a conductive material.

The above described embodiments of the present invention are intended to illustrate and not to limit the present invention. Various alternatives and equivalents are possible. The invention is not limited by the embodiments described herein. Nor is the invention limited to any specific type of semiconductor device. Additions, subtractions, or modifications of features are obvious in view of the present disclosure and are intended to fall within the scope of the present disclosure.

What is claimed is:

1. A bonding structure comprising:
a non-conductive layer having a first surface and a second surface opposite to the first surface; and
at least one conductive pad formed in the non-conductive layer,
wherein the conductive pad comprises:
a vertical pattern portion extending from the first surface to the second surface in the non-conductive layer; and
at least one volume compensation portion formed on a sidewall of the vertical pattern portion.

2. The bonding structure of claim 1, wherein the vertical pattern portion and the volume compensation portion comprise the same conductive material, and the vertical pattern portion and the volume compensation portion is a single uniform body without any detectable boundary between them.

3. The bonding structure of claim 1, wherein the volume compensation portion is formed on the entire sidewall of the vertical pattern portion.

4. The bonding structure of claim 3, wherein a surface of the volume compensation portion facing the non-conductive layer has an at least partially uneven structure.

5. The bonding structure of claim 3, wherein a surface of the volume compensation portion facing the non-conductive layer has a bow structure.

6. The bonding structure of claim 1, wherein each of the non-conductive layer and the conductive pad comprises an upper region adjacent to the first surface of the non-conductive layer and a lower region adjacent to the second surface of the non-conductive layer.

7. The bonding structure of claim 6, wherein the volume compensation portion is positioned in at least one of the upper region and the lower region in the conductive pad.

8. The bonding structure of claim 6, wherein the volume compensation portion is formed in the upper region and the lower region of the conductive pad, and the volume compensation portion in the upper region of the conductive pad has a shape different from a shape of the volume compensation portion in the lower region of the conductive pad.

9. The bonding structure of claim 6, wherein each of the non-conductive layer and the conductive pad further comprises a middle region between the upper region and the lower region, and the volume compensation portion is positioned in at least one of the upper region, the middle region and the lower region.

10. The bonding structure of claim 6, wherein the non-conductive layer comprises a first dielectric layer and a second dielectric layer alternately stacked, and the first and second dielectric layers comprise materials having different etching selectivities.

11. The bonding structure of claim 1, wherein the volume compensation portion is positioned at an upper sidewall of the vertical pattern portion which is located at the first surface or a lower sidewall of the vertical pattern portion which is located at the second surface.

12. The bonding structure of claim 1, wherein the volume compensation portion is spaced apart from the first and second surfaces and an area of the conductive pad exposed through the first and second surfaces is the same as a cross-sectional area of the vertical pattern portion.

13. A semiconductor device comprising:
a first semiconductor component including a first device layer and a first bonding structure electrically connected with the first device layer; and
a second semiconductor component including a second device layer and a second bonding structure electrically connected with the second device layer and hybrid-bonded to the first bonding structure,
wherein each of the first bonding structure and the second bonding structure comprises at least one conductive pad exposed toward a bonding surface and a non-conductive layer formed outside the conductive pad, and
wherein at least one of the conductive pads in the first and second bonding structures comprises a vertical pattern portion formed through the non-conductive layer and at least one volume compensation portion formed on a sidewall of the vertical pattern portion.

14. The semiconductor device of claim 13, wherein at least one of the volume compensation portions comprises at least one protrusion that laterally protrudes from a sidewall of the vertical pattern portion.

15. The semiconductor device of claim 13, wherein the volume compensation portion comprises a plurality of protrusions having different shapes depending on a thickness direction of the conductive pattern.

16. The semiconductor device of claim 13, wherein
the first bonding structure comprises an upper region adjacent to the bonding surface and a lower region adjacent to the first device layer,
the second bonding structure comprises an upper region adjacent to the bonding surface and a lower region adjacent to the second device layer, and
the volume compensation portion is positioned in at least one of the upper region and the lower region of the first and second bonding structures.

17. The semiconductor device of claim 16, wherein the volume compensation portion is formed in the upper region and the lower region, and a shape of the volume compensation portion in the upper region is different from a shape of the volume compensation portion in the lower region.
